(19) United States
(12) Patent Application Publication
(10) Pub. No.: US 2019/0393112 A1
(43) Pub. Date: Dec. 26, 2019

(54) ENCAPSULANT MATERIAL CONTAINING FLUOROPHORES FOR IN-SITU VISUALIZATION OF STRESS IN AN ORGANIC PACKAGE

(71) Applicants: Elizabeth NOFEN, Phoenix, AZ (US); Bharat PENMECHA, Chandler, AZ (US); Arjun KRISHNAN, Chandler, AZ (US); Malavarayan SANKARASUBRAMANIAN, Chandler, AZ (US)

(72) Inventors: Elizabeth NOFEN, Phoenix, AZ (US); Bharat PENMECHA, Chandler, AZ (US); Arjun KRISHNAN, Chandler, AZ (US); Malavarayan SANKARASUBRAMANIAN, Chandler, AZ (US)

(21) Appl. No.: 16/017,464

(22) Filed: Jun. 25, 2018

(51) Int. Cl. H01L 23/29; H01L 25/065; H01L 23/31; H01L 23/538; H01L 21/56; H01L 25/00

(52) U.S. Cl. CPC H01L 23/295; H01L 25/0655; H01L 23/3121; H01L 23/5381; H01L 21/565; H01L 24/16; H01L 23/5385; H01L 23/3135; H01L 23/3142; H01L 25/50; H01L 21/563

(57) ABSTRACT

Embodiments include an encapsulation material, one or more semiconductor packages, and methods of the semiconductor packages. A semiconductor package including dies disposed on a package substrate. The semiconductor package also includes at least one of an underfill layer, a mold layer, and a dielectric layer on or in the package substrate. The semiconductor package further includes an encapsulation material having a fluorescent chemical compound and an epoxy. The encapsulation material may be incorporated into at least one of the underfill layer, the mold layer, and/or the dielectric layer on or in the package substrate. The fluorescent chemical compound of the encapsulation material may include at least one of a poly(vinylcarbazole) (PVCz), a 1,4-Bis(5-phenyl-2-oxazolyl) benzene (POPOP), and/or a plurality of conjugated, aromatic molecules and polymers. The encapsulation material may include at least one of a hardener, a filler, an additive, and/or a polymer.

### FIELD

Embodiments relate to packaging semiconductor devices. More particularly, the embodiments relate to encapsulant materials including fluorophores for in-situ visualization of stresses in an organic semiconductor package and methods for forming such encapsulant materials including fluorophores.

### BACKGROUND

Packaging of semiconductor devices present several problems. One of the main problems involves in-situ and posteriori quantifying stresses generated in an organic package (e.g., a semiconductor device) during assembly, testing, and release. This problem spans across all package architectures. Typically, stresses on a package may generate during temperature cycling (e.g., warpage induced), cure shrinkage of encapsulants (e.g., epoxy molding compound (EMC), a capillary underfill (CUF), etc.), manufacturing (e.g., lamination, flattening, etc.), and post-assembly mechanical processes (e.g., testing, etc.). High stresses at various interfaces or components of the package can lead to mechanical and/or electrical failures.

Existing solutions may include relying on mechanical modeling to provide predictions for material and/or dimensional targets for a given packaging architecture. Mechanical modeling, however, cannot predict the residual stresses generated during the curing of most materials at the substrate level and the assembly level. Additionally, existing solutions generally require an invasive metrology to measure residual stresses at a package level.

For example, some existing solutions employed to measure in-package stresses may include inserting strain gauges and piezo sensors in a mold chase (or the like). These gauges and sensors typically do not provide high spatial resolution, and the presence/inclusion of such gauges and/or sensors into the mold chase may further impact the stress state of the package.

### BRIEF DESCRIPTION OF THE DRAWINGS

Embodiments described herein illustrated by way of example and not limitation in the figures of the accompanying drawings, in which like references indicate similar features. Furthermore, some conventional details have been omitted so as not to obscure from the inventive concepts described herein.

FIG. 1 is an illustration of a cross-sectional view of a semiconductor package having a mold layer, one or more dies, an underfill layer, encapsulation materials, and a package substrate with an embedded interconnect bridge, according to one embodiment.

FIG. 2 is an illustration of a cross-sectional view of a semiconductor packaged system including a die, a substrate, a package substrate, and encapsulation materials, according to one embodiment.

FIG. 3 is a process flow illustrating a method of forming an encapsulation material having a fluorescent chemical compound and an epoxy, where the encapsulation material is disposed on (or incorporated into) at least one of an underfill layer, a mold layer, and a dielectric layer on or in a package substrate, according to one embodiment.

FIG. 4 is a process flow illustrating a method of forming an encapsulation material to determine one or more emission spectras for implementing an induced stress map based on the one or more emission spectras, according to one embodiment.

FIG. 5 is a schematic block diagram illustrating a computer system that utilizes a semiconductor package having a mold layer, one or more dies, an underfill layer, encapsulation materials, and a package substrate with an embedded interconnect bridge, according to one embodiment.

### DETAILED DESCRIPTION

Described herein encapsulant materials having fluorophores for in-situ visualization of stresses in semiconductor packages and methods for forming such encapsulant materials having fluorophores. In particular, for some embodiments, encapsulation materials described below and methods of forming such encapsulation materials include incorporating a fluorescent chemical compound (e.g., a poly(vinylcarbazole) (PVCz) and a 1,4-Bis(5-phenyl-2-oxazolyl) benzene (POPOP)) into an epoxy material (e.g., a mixture of one or more epoxy resins).

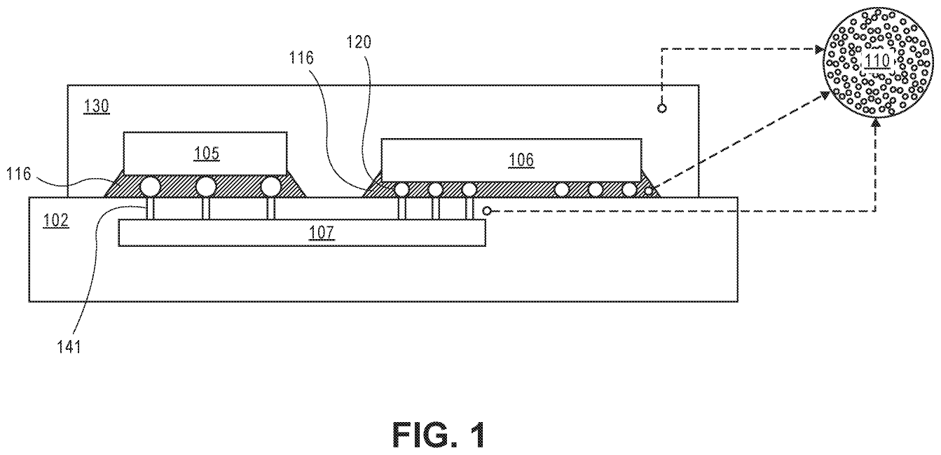

According to some embodiments, a semiconductor package is described (e.g., the semiconductor package 100 shown in FIG. 1). For one embodiment, the semiconductor package includes one or more dies disposed on a package substrate (e.g., the dies 105-106 shown in FIG. 1). In one embodiment, the semiconductor package also includes an underfill layer, a mold layer, and/or a dielectric layer disposed on or in the package substrate (e.g., the underfill layer 116, the mold layer 130, and/or the build-up dielectrics in the package substrate 102 shown in FIG. 1). According to one embodiment, the semiconductor package further includes an encapsulation material having a fluorescent chemical compound and an epoxy (e.g., the encapsulation material 110 shown in FIG. 1).

For additional embodiments, the encapsulation material(s) may be incorporated into at least one of the underfill layer, the mold layer, and the dielectric layer on or in the package substrate (e.g., as shown in FIG. 1 by disposing the encapsulation material 110 in the one or more respective layers). In one embodiment, the epoxy may include a plurality of one or more epoxy resins. In some embodiments, the fluorescent chemical compound of the encapsulation material may include a PVCz, a POPOP, a combination of one or more conjugated, aromatic molecules and polymers, and/or the like. The fluorescent chemical compound of the encapsulation material may have a weight percentage (wt %) of greater than or equal to approximately 0.1% (e.g., ≥0.1% PVCz/POPOP in the encapsulation material (or the epoxy): ≥0.1 g PVCz/POPOP in 100 g of the encapsulation material (or the epoxy)). For example, the encapsulation material may include a weight percentage between approximately 0.1% to 2.0% (or 0.1-2%) of the fluorescent chemical compound. For other embodiments, the encapsulation material may include at least one of a hardener, a filler, an additive, one or more polymers, and/or a combination therein.

As used herein, an “encapsulation material” (also referred to as an encapsulant material) refers to a fluorescent chemical compound incorporated into one or more material(s). As used herein, a “fluorescent chemical compound” refers to one or more mechanochromic fluorophore materials including, but are not limited to, a PVCz, a POPOP, a combination of one or more conjugated, aromatic molecules and polymers, and the like. For some embodiments, the encapsulation material includes the fluorescent chemical compound and at least one or more materials such as, but are not limited to, epoxy materials and/or the like.

According to some embodiments, the encapsulation material described herein may be formed by incorporating the fluorescent chemical compound into the epoxy (or the like), where the epoxy may include at least one of (i) one or more epoxy material(s) of an assembly material being used to form a material/layer in a package substrate and (ii) one or more epoxy material(s) that are independent of the assembly materials (e.g., in an initial form, the encapsulation material may be premixed (e.g., as a powder, a liquid, etc.) and then subsequently incorporated into the one or more epoxies of a respective assembly material). For example, the encapsulation material may include the epoxy (or the epoxy material(s)) which may include, but is not limited to, a plurality of one or more epoxy resins. Additionally, as used herein, the “encapsulation material” refers a material composition having a wide variety of initial forms including, but is not limited to, a layer (e.g., an encapsulation layer), a film, a liquid, and/or a powder (e.g., a premixed powder of the encapsulation material may be subsequently added into any desired material such as an epoxy and/or the like). For example, the encapsulation material may be implemented at a pre B-stage or a B-staged assembly step.

Continuing with the above, an “encapsulation material,” as used herein, refers to a material composition that enables a quantification of stresses at any desired location in an organic package (e.g., the semiconductor package 100 of FIG. 1). For example, to quantify these stresses in the package, the fluorophores of the encapsulation material may include mechanochromic materials/properties which undergo change in a fluorescence emission spectra in response to a mechanical stimulus. Accordingly, in these embodiments, the encapsulation material may be implemented in, but not limited to, packaging materials such as an underfill, a mold, and a build-up dielectric, where each of these packaging materials may have mechanochromic properties by incorporating a specific weight percentage (or mass ratio) of fluorophores (or fluorescent chemical compounds) into the existing packaging materials.

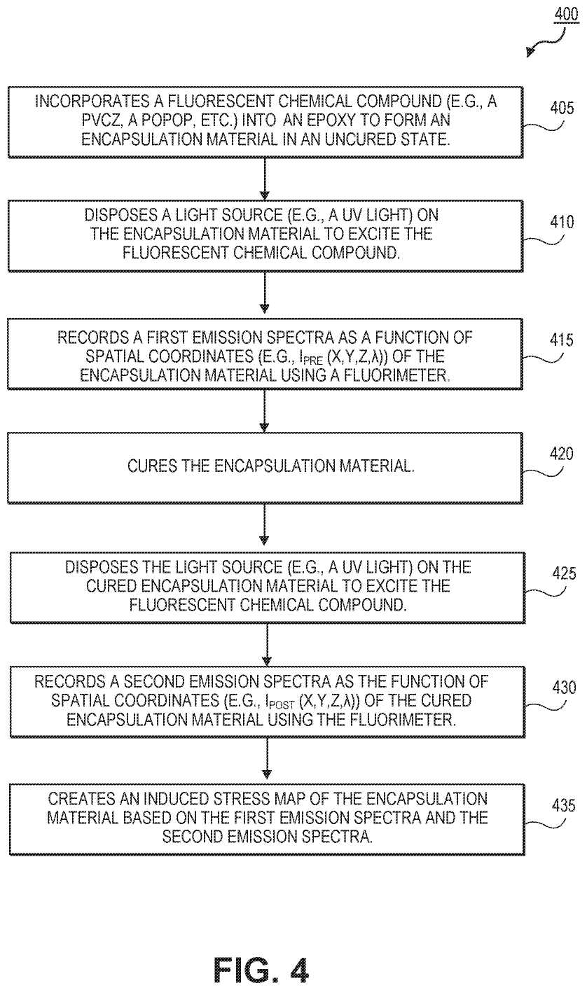

Accordingly, for the embodiments herein, the encapsulation materials improve packaging solutions by incorporating mechanoresponsive and/or mechanochromic materials—which thus allow measurable changes in fluorescent response of the fluorophores to the respective localized mechanical environment. For example, the encapsulation materials may have mechanochromic materials with different excimer complexes that are formed based on the different interactions of the fluorophore molecules within the epoxy matrix (or the polymer matrix) when subjected to induced stress or strain, which may thus be measured and/or quantified (e.g., as described in further detail below in FIG. 4).

The embodiments of the encapsulation material enable a noninvasively detection of residual stresses and strains within the encapsulation materials. For example, the encapsulation material may facilitate with the detection of internal stresses such as solder bump joint stresses that ultimately lead to joint fracture, delamination, and/or package separation. As described above, while existing mechanical modeling is typically used to determine the stress state in semiconductor packages, the existing modeling is an invasive metrology, especially for polymers, when attempting to measure residual stresses at a package level, and cannot predict the residual stresses generated during the curing of materials both in the substrate and assembly levels. Accordingly, for these embodiments, the encapsulation materials described herein enables a noninvasive metrology to measure residual stresses on a semiconductor package during any assembly/packaging/testing steps.

These embodiments of the encapsulation material enable quantifying the stresses at any location (bulk or interfacial) within a semiconductor package, and thus greatly improving the desired material requirements for a robust package design. For example, the encapsulation material enables measuring/quantifying the stresses around an embedded interconnect bridge (or an embedded die)—which are typically not measurable due to the embedded location of the interconnect bridge (or the die) in the package substrate—by providing a feedback loop for a finite element modeling stress verification.

Additional advantages of the encapsulation material described herein include: (1) providing a micron level spatial and temporal resolution; (2) enabling a non-contact impact (noninvasive impact) during the measurement of the stresses in the package; (3) improving the electronic package development by illustrating the nature of internal stresses induced during assembly, test and release; (4) optimizing the design and processing of the semiconductor package and the selection of the packaging materials (e.g., all of these materials and processes directly impact warpage of the package which may be optimized with the encapsulation material); (5) offering a metrology, for example for customers and/or substrate suppliers, to (i) troubleshoot individual package substrate units, (ii) optimize manufacturing (e.g., during a build-up film (BF) lamination), and (iii) reduce variability of warpage in incoming package substrates; (6) enabling a noninvasive detection of internal and residual stresses induced during (i) the processing of the package substrate (e.g., lamination/flattening processes, etc.), (ii) each of the assembly processes of the package substrate, and (iii) the curing processes of the package substrate (e.g., encapsulating a mold layer, a molded underfill (MUF), and/or a capillary underfill (CUF) during a curing process); (7) establishing an automated fluorescence spectroscopy system to detect real time in situ stress regions in the microelectronic semiconductor packages at a fast and low-cost basis; and (8) enabling a non-destructive analysis of epoxy compounds in situ to determine manufacturing defects and product life expectancy.

The technologies described herein may be implemented in one or more electronic devices. Non-limiting examples of electronic devices that may utilize the technologies described herein include any kind of mobile device and/or stationary device, such as microelectromechanical systems (MEMS) based electrical systems, gyroscopes, advanced driving assistance systems (ADAS), 5G communication systems, cameras, cell phones, computer terminals, desktop computers, electronic readers, facsimile machines, kiosks, netbook computers, notebook computers, internet devices, payment terminals, personal digital assistants, media players and/or recorders, servers (e.g., blade server, rack mount server, combinations thereof, etc.), set-top boxes, smart phones, tablet personal computers, ultra-mobile personal computers, wired telephones, combinations thereof, and the like. Such devices may be portable or stationary. In some embodiments, the technologies described herein may be employed in a desktop computer, laptop computer, smart phone, tablet computer, netbook computer, notebook computer, personal digital assistant, server, combinations thereof, and the like. More generally, the technologies described herein may be employed in any of a variety of electronic devices having at least one of a mold layer, one or more dies, an underfill layer, encapsulation materials, and a package substrate with an embedded interconnect bridge (e.g., as shown below in FIG. 1).

In the following description, various aspects of the illustrative implementations will be described using terms commonly employed by those skilled in the art to convey the substance of their work to others skilled in the art. However, it will be apparent to those skilled in the art that the present embodiments may be practiced with only some of the described aspects. For purposes of explanation, specific numbers, materials and configurations are set forth in order to provide a thorough understanding of the illustrative implementations. However, it will be apparent to one skilled in the art that the present embodiments may be practiced without the specific details. In other instances, well-known features are omitted or simplified in order not to obscure the illustrative implementations.

Various operations will be described as multiple discrete operations, in turn, in a manner that is most helpful in understanding the present embodiments, however, the order of description should not be construed to imply that these operations are necessarily order dependent. In particular, these operations need not be performed in the order of presentation.

As used herein the terms “top,” “bottom,” “upper,” “lower,” “lowermost,” and “uppermost” when used in relationship to one or more elements are intended to convey a relative rather than absolute physical configuration. Thus, an element described as an “uppermost element” or a “top element” in a device may instead form the “lowermost element” or “bottom element” in the device when the device is inverted. Similarly, an element described as the “lowermost element” or “bottom element” in the device may instead form the “uppermost element” or “top element” in the device when the device is inverted.

FIG. 1 is an illustration of a cross-sectional view of a semiconductor package 100 having a mold layer 130, one or more dies 105-106, an underfill layer 116, encapsulation materials 110, and a package substrate 102 with an embedded interconnect bridge 107, according to one embodiments.

In some embodiments, the semiconductor package 100 includes the encapsulation materials 110 incorporated into at least one of the mold layer 130, the underfill layer 116, and the package substrate 102. As described above, the encapsulation materials 110 include a fluorescent chemical compound (e.g., a PVCz, a POPOP, etc.). The fluorescent chemical compound may include one or more fluorophores (or fluorochromes) that may re-emit light upon light excitation. The fluorophores may include, but are not limited to, at least one or more of conjugated groups, aromatic groups, polymers, planar or cyclic molecules with one or more pi bonds, combinations therein, and the like. Furthermore, the encapsulation materials 110 may include the fluorescent chemical compound incorporated into an epoxy material (e.g., one or more epoxy resins). Note that the encapsulation materials 110 are not limited to epoxy materials.

According to some embodiments, the fluorescent chemical compound(s) of the encapsulation materials 110 may include one or more mechanochromic fluorophore materials. The encapsulation materials 110 may have a mass ratio of mechanochromic fluorophore material per gram of epoxy (or M_{fluorophore}:M_{epoxy}) that is greater than or equal to approximately 0.1:100 (or ≥0.1%). In some embodiments, the encapsulation material 110 may include a weight percentage between approximately 0.1% to 2% of the fluorescent chemical compound, or, in other embodiments, the encapsulation material 110 may include a weight percentage greater than or equal to approximately 0.1% (or ≥0.1%) of the fluorescent chemical compound.

As described in further detail below, the encapsulation materials 110 may be incorporated into one or more materials of the semiconductor package 100 to determine (or quantify) the stresses at any location in the semiconductor package 100. For example, the fluorophores of the encapsulation materials 110 may include mechanochromic materials that undergo changes in a fluorescence emission spectra in response to a mechanical stimulus, which enable detection of stresses in the semiconductor package 100. Accordingly, the encapsulation materials 110 may be judiciously added into the one or more materials (or assembly materials) of the semiconductor package 100—e.g., the package substrate 102 (or the build-up layers of the package substrate 102), the underfill layer 116, and/or the mold layer 130—such that these materials incorporate the mechanochromic materials/properties described herein.

Referring back to FIG. 1, the semiconductor package 100 may include the dies 105-106 disposed on the package substrate 102. In one embodiment, the mold layer 130 may be disposed on and around the dies 105-106, the underfill layer 116, and the package substrate 102. The dies 105-106 may be electrically coupled to the package substrate 102 via the solder balls 120, the underfill layer 116, the interconnects 141, and the embedded interconnect bridge 107.

According to some embodiments, the package substrate 102 may include, but is not limited to, a substrate, a build-up structure, a printed circuit board (PCB), and a motherboard. For one embodiment, the package substrate 102 is a PCB. For one embodiment, the PCB is made of an FR-4 glass epoxy base with thin copper foil laminated on both sides. For certain embodiments, a multilayer PCB can be used, with pre-preg and copper (Cu) foil used to make additional layers. For one embodiment, the package substrate 102 is a multilayer PCB having one or more build-up dielectric layers, where each dielectric layer can be a photosensitive dielectric layer. In some embodiments, the one or more build-up dielectric layers 102 may form part or all of the package substrate (or the PCB). For one embodiment, the package substrate 102 may also include conductive layers having one or more metallic (or Cu) lines/traces, pads, vias, via pads, planes, holes, and/or interconnects 141.

As illustrated in FIG. 1, in some embodiments, the package substrate 102 may include the embedded interconnect bridge 107 (EMIB) to electrically couple the die 105 to the die 106. The package substrate 102 may also include the interconnects 141 to electrically couple the EMIB 107 to the dies 105-106. The package substrate 102 may include the EMIB 107, the interconnects 141, and/or one or more additional routing layers (or build-up layers). For example, the additional routing layers may be simple or complex, may be for coupling to other packages (or dies), and/or may form part or all of the organic build-up layers having conductive layers, resist layers, and/or dielectric layers.

Furthermore, the package substrate 102 may incorporate (or embed) the encapsulation materials 110 into the one or more build-up dielectric layers. In particular embodiments, the package substrate 102 may have a dielectric layer incorporated with the encapsulation materials 110 as the dielectric layer and the encapsulation materials 110 are disposed on and around the EMIB 107. For one embodiment, the dielectric layer may be a polymer material including, but not limited to, a dry film resist (DFR), a polyimide, an epoxy, and/or a BF. In one embodiment, the dielectric layer may be one layer in a stack, where the stack may include a plurality of dielectric layers used to form part or all of the build-up structure(s) of the package substrate 102.

In some embodiments, the encapsulation materials 110 disposed in the package substrate 102 (or in any other material of the semiconductor package 100 (e.g., the underfill and mold layers 116 and 130)) may include one or more epoxy materials. For example, the epoxy materials may include, but are not limited to, a plurality (or a mixture) of epoxy resins, which may be subsequently used (or incorporated) into the dielectric layer(s) of the package substrate 102. The epoxy materials may be homopolymerized or may include one or more hardeners such as, but not limited to, amines, phenols, anhydrides, and/or combinations therein (or the like).

For other embodiments, the encapsulation materials 110 may include one or more additional materials including, but not limited to, acrylates, bismaleimides, polyesters, polyimides, polyolefins, polystyrene, polyurethanes and/or combinations therein (or the like). According to other embodiments, the encapsulation materials 110 may also include one or more filler materials to enhance mechanical properties in the encapsulation materials 110 (e.g., enabling mechanical property enhancements for the encapsulation materials 110 incorporated into the underfill layer 116). The filler materials may include, but are not limited to, silica, alumina, boron nitride, zinc oxide, and/or combinations therein (or the like). The filler materials may be used with a multitude of average particle sizes and/or a wide variety of particle sizes.

The semiconductor package 100 may include one or more connections between the package substrate 102, the EMIB 107, and the dies 105-106—e.g., including some or all of the solder bumps 120—where the one or more connections may further include one or more interconnect structures and underfill layers 116. For some embodiments, these interconnect structures/connections (e.g., the interconnects 141) may variously comprise an alloy of nickel, palladium, and/or tin (and, in some embodiments, Cu).

For one embodiment, each of the one or more dies 105-106 may include, but is not limited to, a semiconductor die, an electronic device (e.g., a wireless device), an integrated circuit (IC), a central processing unit (CPU), a microprocessor, a platform controller hub (PCH), a memory, and/or a field-programmable gate array (FPGA). The dies 105-106 may be formed from a material such as silicon and have circuitry thereon that is to be coupled to the package substrate 102. The dies 105-106 have a bottom surface that is electrically coupled to the package substrate 102 via the underfill layer 116, which is understood to also include first level interconnects (FLI), such as the solder bumps 120. For example, the underfill layer 116 may be used on a ball grid array (BGA), a pin grid array (PGA), a land grid array (LGA), or any other connectivity packaging. For one embodiment, the underfill layer 116 may include controlled collapse chip connection (C4) bumps that electrically couple pads on the dies 105-106 and on the substrate 102.

For one embodiment, the underfill layers 116 may be one or more polymers that are incorporated with the fluorescent chemical compounds of the encapsulation materials 110. The underfill layer 116 (or the underfill material) may be disposed (or injected) between the dies 105-106 and the package substrate 102. The underfill layers 116 incorporated with the encapsulation materials 110 may be implemented to enhance the mechanical properties (such as adhesion) between the dies 105-106 and the package substrate 102. The underfill layers 116 may also be implemented to determine (or measure/quantify) one or more stresses within the underfill layers 116. The underfill layers 116 may be at least one of MUFs and CUFs. The underfill layers 116 may have a wide variety of initial forms including, but not limited to, a layer, a film, a liquid, and/or a powder. The underfill layers 116 may be pre B-stage or B-staged. The underfill layers 116 may be disposed using one or more packaging processes, including, but not limited to, dispensing, printing, curtain coating, molding, lamination, and/or the like. The underfill layers 116 may also include one or more filler materials such as silica, alumina, boron nitride, zinc oxide, and/or combinations therein (or the like). The underfill layers 116 may further include additives including, but not limited to, colorants, catalysts, inhibitors, ion trappers, stress absorbers, polymers, surfactants, binding agents, fluxing agents, and/or combinations therein (or the like).

In some other embodiments, the mold layer 130 (or an encapsulation layer) may be disposed over and around the dies 105-106, the underfill layer 106, and the package substrate 102. The mold layer 130 may include one or more epoxy materials (or the like) that are incorporated with the fluorescent chemical compounds of the encapsulation materials 110. The mold layer 130 may be disposed (or molded/laminated) above the dies 105-106, the underfill layer 116, and the package substrate 102. The mold layer 130 may be used to protect the semiconductor package 100 from the environment. For one embodiment, the mold layer 130 may be cured after the overmolding. In other embodiments, the mold layer 130 incorporated with the encapsulation materials 110 may help to protect and cover the semiconductor package 100 from humidity, photons, corrosion and damage.

For one embodiment, the mold layer 130 may include an epoxy (e.g., a soft epoxy, a stiff epoxy, opaque epoxy, etc.) and a fluorescent chemical compound (i.e., forming the encapsulation materials 110). The mold layer 130 may further include one or more filler materials and/or additives (as described above). The mold layer 130 may be formed (or incorporated) with the encapsulation materials 110 and may be subsequently dispensed onto/over the package substrate 102—rather than using injection, compression, or transfer mold processes. Note that, as shown in FIG. 1, the mold layer 130 may form a rectangular enclosure, but may also form any arbitrary shape/texture including a hemispherical shape, a capsule-like shape, a honeycombed shape, a round shape, etc.

As described above, the encapsulation materials 110 may be incorporated into at least one of the mold layer 130, the underfill layer 116, and the build-up layers of the package substrate 102. According to some embodiments, the fluorescent chemical compound of the encapsulation materials 110 may have a weight percentage of greater than or equal to approximately 0.1% (or ≥0.1 g PVCz/POPOP in 100 g of the encapsulation materials 110). As described above, the encapsulation materials 110 may further include, but is not limited to, at least one of a hardener, a filler, an additive, a polymer, and a combination therein. In one embodiment, the encapsulation materials 110 may include a first mass ratio (M_{fluorophore}:M_{epoxy}) of approximately (0.1 to 2.0):100, and a second mass ratio (Mᵣₑₛᵢₙ:M_{hardener}) of approximately 100:(27±7). In other embodiments, the encapsulation materials 110 may have mass ratios of a M_{fluorophore}:M_{epoxy} of approximately 0.1:100 or greater, and a Mᵣₑₛᵢₙ:M_{hardener} of approximately 100:27 or greater.

In some additional embodiments, the encapsulation materials 110 may be formed to include one or more different materials (or chemical properties) that are specific to at least one of the mold layer 130, the underfill layer 116, and the build-up layers of the package substrate 102. For example, the encapsulation materials 110 incorporated into the mold layer 130 may have one or more different materials than the encapsulation materials 110 incorporated into the underfill layer 116 (e.g., the encapsulation materials 110 incorporated into the underfill layer 116 may have one or more filler materials that may not be included in the encapsulation materials 110 incorporated into the mold layer 130). Likewise, the encapsulation materials 110 incorporated into the build-up layers of the package substrate 102 may have one or more different materials than the encapsulation materials 110 incorporated into the mold layer 130 and/or the underfill layer 116 (e.g., the encapsulation materials 110 incorporated into the build-up layers of the package substrate 102 may have one or more epoxy materials (or hardeners) that may not be included in the encapsulation materials 110 incorporated into the mold layer 130 and/or the underfill layer 116).

Note that the semiconductor package 100 of FIG. 1 may include fewer or additional packaging components and/or materials based on the desired packaging design.

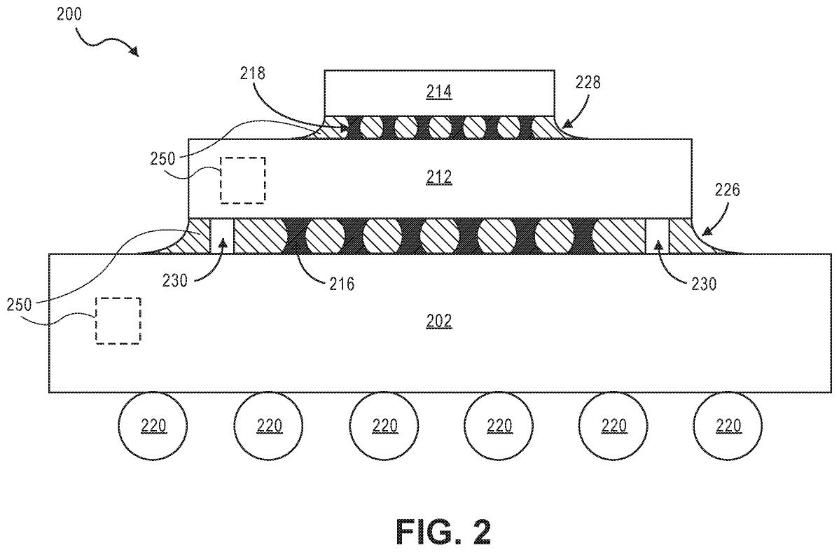

FIG. 2 is an illustration of cross-sectional view of a semiconductor packaged system 200 including a die 214, a substrate 212, a package substrate 202, and encapsulation materials 250, according to one embodiment. In particular, FIG. 2 illustrates the semiconductor package 200 including the die 214, the substrate 212 (or an interposer), interconnect structures (e.g., the plurality of bumps disposed below the die 214 and the substrate 212), and the package substrate 202, where at least one of the substrate 212, the package substrate 202, and the underfill layer(s) 226 and 228 may include the encapsulation materials 250 as described herein. For some embodiments, the encapsulation materials 250 may include, but is not limited to, at least one of a fluorescent chemical compound (e.g., a PVCz, a POPOP, etc.), an epoxy material (e.g., a plurality of one or more epoxy resins), a hardener, a filler, an additive, a polymer, and a combination therein.

In some embodiments, the encapsulation materials 250 may be incorporated into at least one of the substrate 212, the package substrate 202, and the underfill layer(s) 226 and 228 to determine one or more stresses at substantially any location of the semiconductor package 200 (i.e., any location incorporated with the encapsulation materials 250). Note that the semiconductor package 200 is not limited to the illustrated semiconductor packaged system, and thus may be designed/formed with fewer, alternate, or additional packaging components and/or with different interconnecting structures.

For one embodiment, the semiconductor package 200 may dispose (or incorporate) the encapsulation materials 250 into the substrate 212, the package substrate 202, and/or the underfill layer(s) 226 and 228 (e.g., as shown with the package substrate 102 and/or the underfill layer of FIG. 1). Note that the package substrate 202 (or the substrate 212) and the underfill layers 226 and 228 may be similar to the package substrate 102 and the underfill layer 116 of FIG. 1, respectively.

According to one embodiment, the semiconductor package 200 is merely one example of an embodiment of a semiconductor packaged system. For one embodiment, the semiconductor package 200 may include a LGA package and/or a PGA package. For one embodiment, the die 214 (or an integrated circuit die) is coupled to the substrate 212 (e.g., an interposer) via one or more bumps/joints formed from respective microbumps. As described above, a solder joint formed by soldering of a microbump according to an embodiment may itself be referred to as a “bump” and/or a “microbump.” Additionally, for other embodiments, the die 214, the substrate 212, and the package substrate 202 may be coupled using anisotropic conductive film (ACF). For one embodiment, the substrate 212 may be, but is not limited to, at least one of a silicon interposer and a die having through silicon vias (TSVs) and the encapsulation materials 250. For an alternate embodiment, the semiconductor package 200 may omit the substrate/interposer 212.

For some embodiments, the semiconductor package 200 may have the die 214 disposed on the interposer 212, where both the stacked die 214 and interposer 212 are disposed on the package substrate 202. According to some embodiments, the package substrate 202 may include, but is not limited to, a package, a substrate, a PCB, and a motherboard. For one embodiment, the package substrate 202 is a PCB. For one embodiment, the PCB is made of an FR-4 glass epoxy base with thin copper foil laminated on both sides. For certain embodiments, a multilayer PCB can be used, with pre-preg and copper foil used to make additional layers. For one embodiment, the package substrate 202 is a multilayer PCB having the encapsulation materials 250 incorporated into one or more dielectric layers, where each dielectric layer can be a photosensitive dielectric layer. For some embodiments, holes may be drilled in the PCB 202. For one embodiment, the PCB 202 may also include conductive layers that comprise copper lines/traces, metallic pads, vias, via pads, planes, and/or holes.

For one embodiment, the die 214 may include, but is not limited to, a semiconductor die, an electronic device (e.g., a wireless device), an integrated circuit, a central processing unit (CPU), a microprocessor, a platform controller hub (PCH), a memory, and a field-programmable gate array (FPGA). The die 214 may be formed from a material such as silicon and have circuitry thereon that is to be coupled to the interposer 212. Although some embodiments are not limited in this regard, the package substrate 202 may in turn be coupled to another body, for example, a computer motherboard. One or more connections between the package substrate 202, the interposer 212, and the die 214—e.g., including some or all of bumps 216, 218, and 220—may include one or more interconnect structures and underfill layers 226 and 228, where these interconnect structures and underfill layers 226 and 228 may include the encapsulation materials 250. In some embodiments, these interconnect structures (or connections) may variously comprise an alloy of nickel, palladium, and tin (and, in some embodiments, Cu).

Connections between the package substrate 202 and another body may be made using any suitable structure, such as the illustrative bumps 220 shown. The package substrate 202 may include a variety of electronic structures formed thereon or therein. The interposer 212 may also include electronic structures formed thereon or therein, which may be used to couple the die 214 to the package substrate 202. For one embodiment, one or more different materials may be used for forming the package substrate 202 and the interposer 212, including the encapsulation materials 250. In certain embodiments, the package substrate 202 is an organic substrate made up of one or more layers of polymer base material, with conducting regions for transmitting signals. In certain embodiments, the interposer 212 is made up of a ceramic base material including metal regions for transmitting signals. Although some embodiments are not limited in this regard, the semiconductor package 200 may include gap control structures 230—e.g., positioned between the package substrate 202 and the interposer 212. Such gap control structures 230 may mitigate a change in the height of the gap between the package substrate 202 and the interposer 212, which otherwise might occur during reflowing while die 214 is attached to interposer 212. Note that the semiconductor package 200 includes the underfill layer 228 between the interposer 212 and the die 214, and the underfill layer 226 between the package substrate 202 and the interposer 212. For one embodiment, the underfill layers/materials 226 and 228 may include the encapsulation materials 250 and one or more polymers that are injected between the layers. For other embodiments, the underfill layer(s) 226 and 228 may be MUF(s).

Note that the semiconductor packaged system 200 may include fewer or additional packaging components and/or materials based on the desired packaging design.

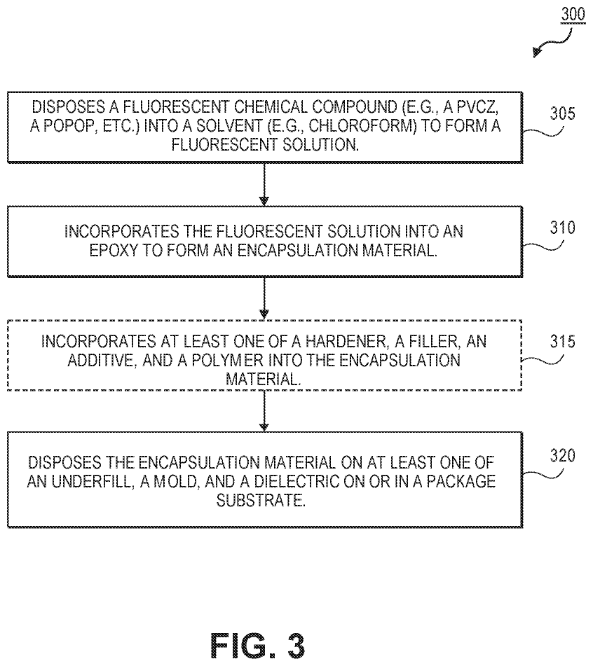

FIG. 3 is a process flow 300 illustrating a method of forming an encapsulation material(s) having a fluorescent chemical compound and an epoxy, where the encapsulation material is disposed on (or incorporated into) at least one of an underfill layer, a mold layer, and a dielectric layer on or in a package substrate, according to one embodiment. For one embodiment, the process flow 300 includes one or more steps used to form the encapsulation materials as described herein (e.g., the encapsulation materials 110 and 250 of FIGS. 1-2). According to one embodiment, the process flow 300 may be similar to the process flow implemented to form the semiconductor package 100 of FIG. 1.

Specifically, the process flow 300 may be used to form and incorporate the encapsulation materials into a semiconductor package (e.g., as shown with the semiconductor packages 100 and 200 of FIGS. 1-2), which enhances the semiconductor package as one or more stresses may be identified (or determined/measured) at substantially any location in the encapsulation materials that are incorporated into the one or more layers/materials/components of the semiconductor package (e.g., as shown with the incorporated encapsulation materials 110 and 250 of FIGS. 1-2), according to one embodiment. The illustrated embodiments of the process flow 300 of forming the encapsulation materials is described, however it is to be appreciated that the described features are not limiting and may be formed using (i) different processing operations, materials, and/or packing structures, and/or (ii) fewer or additional materials and/or packaging components. Note that well-known processes/features of the process flow 300 are omitted or simplified in order not to obscure the illustrative implementations.

At block 305, the process flow 300 disposes (or combines) a fluorescent chemical compound (e.g., a PVCz, a POPOP, etc.) into a solvent (e.g., chloroform) to form a fluorescent solution. At block 310, the process flow 300 incorporates the fluorescent solution into an epoxy to form an encapsulation material (e.g., the encapsulation materials 110 and 250 of FIGS. 1-2). At block 315, the process flow 300 may incorporate at least one of a hardener, a filler, an additive, and a polymer into the encapsulation material. In on embodiment, at block 315, the process flow 300 may incorporate, but is not limited to include, the hardener, the filler, the additive, and/or the polymer into the encapsulation material. As such, in an alternate embodiment, the process flow 300 may implement block 310 and then proceed directly to block 320. At block 320, the process flow 300 disposes the encapsulation material on at least one of an underfill, a mold, and a dielectric on or in a package substrate (e.g., as shown in FIGS. 1-2).

For some embodiments, as described above, the encapsulation material(s) may have at least one of a first set of mass ratio(s), a second set of mass ratio(s), and a third set of mass ratio(s), where each set of mass ratio(s) may be approximately the same or different from one another. For example, the encapsulation materials having the first set of mass ratio(s) may be incorporated into the underfill, the second set of mass ratio(s) may be incorporated into the mold, and/or the third set of mass ratio(s) may be incorporated into the dielectric. In these embodiments, the one or more sets of mass ratios may be implemented (or formed) based on the desired packaging application and/or materials.

In some embodiments, such as in blocks 310-320, the encapsulation material have a plurality of initial forms (or states) including, but not limited to, a layer (e.g., an encapsulation layer), a film, a liquid, and/or a powder (e.g., a premixed powder of the encapsulation material may be subsequently added into any desired material such as an epoxy and/or the like). In other embodiments, the encapsulation material may be implemented at a pre B-stage or a B-staged assembly (or curing) step. Accordingly, the encapsulation material may be disposed in/on the package substrate using a plurality of assembly processes, including, but not limited to, dispensing, printing, curtain coating, molding, lamination, and/or the like.

For one embodiment, the process flow 300 of disposing the fluorescent chemical compound into the solvent to form the fluorescent solution may include combining a solution ratio of 0.05 g or greater of the fluorescent chemical compound (e.g., the PVCz) in 3 mL or greater of the solvent (e.g., the chloroform) with, for example, an ultrasonic probe sonicator in an ice bath (or the like) to form the fluorescent solution. The fluorescent solution may then be incorporated/added into the epoxy (or the one or more resins) and thoroughly dispersed with the sonicator in the ice bath to form the encapsulation material—which is homogeneously dispersed within the epoxy.

In one embodiment, the encapsulation material may be placed under vacuum at 60° C. to thoroughly evaporate the solvent until the mass of the encapsulation material is stable. In other embodiments, after the encapsulation material is evaporated and cooled to room temperature, one or more hardeners may be incorporated into the encapsulation material in the ice bath to prevent any premature curing. Additionally, in these embodiments or other embodiments, the process flow may incorporate the hardeners, fillers, additives, and/or polymers into the encapsulation material at this stage of the process flow or during any other stage of the process flow. Lastly, after the encapsulation material is homogeneous, the encapsulation material may be disposed (or deposited/poured/injected/molded/etc.) into one or more materials (or components) of the semiconductor package (or the package substrate) (e.g., the underfill, the mold, and/or the build-up layers) and may be allowed to cure based on the form (or state) of the encapsulation material.

The encapsulation materials described herein may include a fluorescence. The fluorescence may be a property of organic molecules having a conjugated network of delocalized pi bonding, where the electrons in the p-orbitals are free to move throughout the molecule (e.g., in aromatic rings). In general, a larger conjugated system corresponds to greater fluorescent properties for the molecule. For mechanochromic species (e.g., mechanochromic fluorophore materials), one or more different excimer complexes may form—based on the different interactions of the fluorophore molecules within the epoxy (or the polymer matrix)—when subjected to induced stress or strain. In some embodiments, the encapsulation material may include one or more mechanochromic species to determine (e.g., by measuring/quantifying) one or more stresses (e.g., internal and residual stresses) at substantially any location within the one or more materials of the semiconductor package.

These embodiments enable a noninvasive (or non-destructive) analysis of the encapsulation material by using, for example, a fluorescence spectroscopy to detect and measure the mechanochromic species in the encapsulation material in situ. This noninvasive analysis of the encapsulation material establishes an automated fluorescence spectroscopy system to detect real-time in situ stress regions in the semiconductor packages on a fast and low cost basis. For example, when applied to the epoxy materials/compounds used in electronic packaging, this analysis may help determine manufacturing defects and product life expectancy.

In some embodiments, the encapsulation material may include an opaque, gray-brown color to reflect the light-brown crystalline structure of the fluorophore (e.g., a PVCz). In other embodiments, the encapsulation material may include an opaque color, but having a light fluorescent yellow-white color, to reflect the fluorescent yellow nature of a pure fluorophore (e.g., a POPOP).

Additionally, in some embodiments, a first encapsulation material having a PVCz may generate a lower fluorescence per mole than a second encapsulation material having a POPOP due to the smaller conjugated systems on the polyethylene backbone of the PVCz compared to the large conjugated system throughout a single molecule of the POPOP. This enables one or more encapsulation materials to have one or more varying fluorescence levels. For example, in some embodiments, a PVCz-incorporated encapsulation material may have a lower flexibility to move upon a strain/stress to form the higher fluorescent active confirmations, while a POPOP-incorporated encapsulation material may have a smaller molecule (rather than a polymer) to move with a higher flexibility (or more freedom) to adjust in response to a strain/stress, resulting in an increased response to the applied strain/stress.

Accordingly, the encapsulation materials may display one or more varying emission spectras. For example, in some embodiments, a PVCz-incorporated encapsulation material may display a first intensity approximately between 500-550 nm, while a POPOP-incorporated encapsulation material may display a second intensity that is greater than the first intensity, where the second intensity may have a highly-increased intensity of approximately 550 nm or greater at the selected excitation light intensity, gain, and exposure parameters. These embodiments enable for one more encapsulation materials to be selected/incorporated into the one or more different materials of the semiconductor package based on the desired packaging design, application, testing, etc.

Note that the encapsulation material formed by the process flow 400 may include fewer or additional materials based on the desired packaging design. Also note that measuring the encapsulation material described by the process flow 400 may include fewer or additional steps based on the desired results.

FIG. 4 is a process flow 400 illustrating a method of forming an encapsulation material to determine one or more emission spectras for implementing an induced stress map based on the one or more emission spectras, according to one embodiment. In particular, FIG. 4 illustrates a process flow 400 for a method of forming an encapsulation material(s) having a fluorescent chemical compound and an epoxy, where the encapsulation material is disposed on (or incorporated into) at least one of an underfill layer, a mold layer, and a dielectric layer on or in a semiconductor package (or a package substrate), according to one embodiment. For one embodiment, the process flow 400 includes one or more steps used to form the encapsulation materials as described herein (e.g., the encapsulation materials described above in FIGS. 1-3). According to one embodiment, the process flow 400 may include one or more materials and components implemented to form the semiconductor package 100 of FIG. 1.

Specifically, the process flow 400 enables a method for determining and quantifying one or more cure induced stresses in the encapsulation material that may be incorporated into the semiconductor package (e.g., as shown with the semiconductor packages 100 and 200 of FIGS. 1-2), according to ne embodiment. The illustrated embodiments of the process flow 400 for determining and quantifying one or more cure induced stresses in the encapsulation material is described, however it is to be appreciated that the described features are not limiting and may be formed using different testing, assembly, and processing operations. Note that well-known processes/features of the process flow 400 are omitted or simplified in order not to obscure the illustrative implementations. Also note that process flow 400 may have one or more similarities to the above process flow 300 of FIG. 3.

At block 405, the process flow 400 incorporates a fluorescent chemical compound (e.g., a PVCz, a POPOP, etc.) into an epoxy (e.g., one or more epoxy resins) to form an encapsulation material in an uncured state. At block 410, the process flow 400 shines a light source (e.g., a UV light) on the encapsulation material to excite the fluorescent chemical compound. At block 415, the process flow 400 records a first emission spectra as a function of spatial coordinates (e.g., Iₚᵣₑ (x,y,z,λ)) of the encapsulation material using, for example, a fluorimeter or the like. At block 420, the process flow 400 cures the encapsulation material.

At block 425, the process flow 400 dispose (or shines) the light source (e.g., a UV light) on the cured encapsulation material to excite the fluorescent chemical compound. At block 430, the process flow 400 records a second emission spectra as the function of spatial coordinates (e.g., Iₚₒₛₜ (x,y,z,λ)) of the cured encapsulation material using the fluorimeter. At block 435, the process flow 400 creates an induced stress map of the encapsulation material based on the first emission spectra and the second emission spectra (e.g., determining and quantifying the difference(s) between Iₚₒₛₜ (x,y,z,λ) and Iₚᵣₑ (x,y,z,λ) to create the induced stress map).

The metrology used to detect and measure/record the mechanochromic response(s) of the encapsulation material may require a UV source of the wavelength of excitation of the fluorophore and a fluorimeter (or the like) with good spatial and temporal resolution. In some embodiments, this metrology (or a similar metrology/process flow) may be used to detect and measure the stresses induced during, but not limited to, temperature cycling, testing, different curing profiles of the material, etc. For example, before thermally curing the encapsulation material, a fluorescent microscope may be used to determine and/or measure whether there were any observable fluorescent signals in the uncured liquid encapsulation material. Thereafter, after thermally curing the encapsulation material, the fluorescent microscope may be used to determine and/or measure whether there were any observable fluorescent signals in the cured encapsulation material, indicating the cure-induced residual stresses within the encapsulation material (e.g., when using the UV fluorescence microscopy, these residual stresses may be exhibited as a white color to show the most strained areas).

The process flow may include determining one or more integrated fluorescence density values to depict the relative fluorescence intensities of the one or more encapsulation materials, such as a PVCz-incorporated encapsulation material, a POPOP-incorporated encapsulation material, etc. The process flow may determine the one or more integrated fluorescence density values by comparing the bulk area (or unstrained locations/areas) and the metal-encapsulation material cured interface area (or strained locations/areas), which includes the area(s) adjacent to the cured interface area. In one embodiment, the POPOP-incorporated encapsulation material may exhibit/depict a first overall fluorescence density, and the PVCz-incorporated encapsulation material may exhibit/depict a second overall fluorescence density comparatively, where the first overall fluorescence density may be comparatively greater than the second overall fluorescence density. For one embodiment, comparatively, the first overall fluorescence density of the POPOP-incorporated encapsulation material (i) may be approximately 4-5 times (4-5×) greater than the second overall fluorescence density of PVCz-incorporated encapsulation material, and (ii) may also include the largest change in fluorescence density in the strained regions/areas.

In order to quantitatively correlate the amount of fluorescence intensity with the amount of internal stress in situ, a calibration curve may be desired. This calibration curve may be used for the package application and the following scale-up of the process, as well as to correlate with finite element method (FEM) modeling. In one embodiment, after the calibration curve is developed, an automated fluorescence spectroscopy system may be established to detect real time in situ stress regions in the microelectronic packages on a fast and low cost basis. Note that the fluorophore-incorporated encapsulation material(s) are targeted to be disposed (or incorporated) into the assembly materials during, for example, pathfinding and technology development (TD) stages to determine and measure the stresses generated. For example, the fluorescent signals may be observed in an epoxy assembly material, and a transparent quartz die may be used to observe the stress-induced fluorescence(s) under the die, where the signals and the stress-induced fluorescence(s) may be observed by a fluorescence microscope, a fluorometer, or the like.

Note that the encapsulation material formed by the process flow 400 may include fewer or additional materials based on the desired packaging design. Also note that measuring the encapsulation material described by the process flow 400 may include fewer or additional steps based on the desired results.

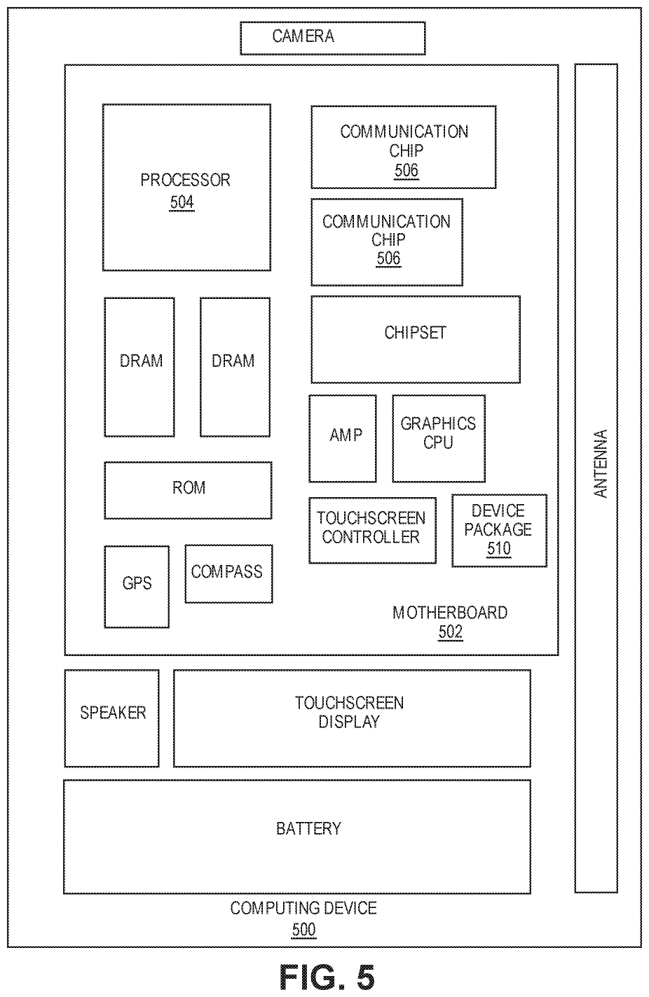

FIG. 5 is a schematic block diagram illustrating a computer system 500 that utilizes a semiconductor package 510 (or a device package) having a mold layer, one or more dies, an underfill layer, encapsulation materials, and a package substrate with an EMIB, according to one embodiment. FIG. 5 illustrates an example of computing device 500. Computing device 500 houses motherboard 502. For one embodiment, motherboard 502 may be similar to the package substrates 102 and 202 of FIGS. 1-2. Motherboard 502 may include a number of components, including but not limited to processor 504, device package 510 (or semiconductor package), and at least one communication chip 506. Processor 504 is physically and electrically coupled to motherboard 502. For some embodiments, at least one communication chip 506 is also physically and electrically coupled to motherboard 502. For other embodiments, at least one communication chip 506 is part of processor 504.

Depending on its applications, computing device 500 may include other components that may or may not be physically and electrically coupled to motherboard 502. These other components include, but are not limited to, volatile memory (e.g., DRAM), non-volatile memory (e.g., ROM), flash memory, a graphics processor, a digital signal processor, a crypto processor, a chipset, an antenna, a display, a touchscreen display, a touchscreen controller, a battery, an audio codec, a video codec, a power amplifier, a global positioning system (GPS) device, a compass, an accelerometer, a gyroscope, a speaker, a camera, and a mass storage device (such as hard disk drive, compact disk (CD), digital versatile disk (DVD), and so forth).

At least one communication chip 506 enables wireless communications for the transfer of data to and from computing device 500. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. At least one communication chip 506 may implement any of a number of wireless standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. Computing device 500 may include a plurality of communication chips 506. For instance, a first communication chip 506 may be dedicated to shorter range wireless communications such as Wi-Fi and Bluetooth and a second communication chip 506 may be dedicated to longer range wireless communications such as GPS, EDGE, GPRS, CDMA, WiMAX, LTE, Ev-DO, and others.

Processor 504 of computing device 500 includes an integrated circuit die packaged within processor 504. Device package 510 may be, but is not limited to, a substrate, a packaging/package substrate, and/or a PCB. Device package 510 may include one or more encapsulation materials having a fluorescent chemical compound (e.g., a PVCz, a POPOP, etc.) and an epoxy material (e.g., one or more epoxy resins) incorporated into one or more material/components of the device package 510 and/or the computing device 500 (e.g., incorporated into an underfill layer, a mold layer, and/or a dielectric layer of a package/device as illustrated in FIGS. 1-2). Device package 510 may also include any other components from the figures described herein.

Note that device package 510 may be a single component/device, a subset of components, and/or an entire system, as the materials, features, and components may be limited to device package 510 and/or any other component of the computing device 500 that may need fluorophore-incorporated encapsulation materials (e.g., the motherboard 502, the processor 504, the antenna of the computing device 500, and/or any other component of the computing device 500).

For certain embodiments, the integrated circuit die may be packaged with one or more devices on a package substrate that includes a thermally stable RFIC and antenna for use with wireless communications and the device package, as described herein, to reduce the z-height of the computing device. The term “processor” may refer to any device or portion of a device that processes electronic data from registers and/or memory to transform that electronic data into other electronic data that may be stored in registers and/or memory.

At least one communication chip 506 also includes an integrated circuit die packaged within the communication chip 506. For some embodiments, the integrated circuit die of the communication chip may be packaged with one or more devices on a package substrate that includes one or more device packages, as described herein.

In the foregoing specification, embodiments have been described with reference to specific exemplary embodiments thereof. It should be borne in mind, however, that all of these and similar terms are to be associated with the appropriate physical quantities and are merely convenient labels applied to these quantities. It will be evident that various modifications may be made thereto without departing from the broader spirit and scope. The specification and drawings are, accordingly, to be regarded in an illustrative sense rather than a restrictive sense.

The following examples pertain to further embodiments. The various features of the different embodiments may be variously combined with some features included and others excluded to suit a variety of different applications.

The following examples pertain to further embodiments:

Example 1 is a semiconductor package comprising of dies on a package substrate; at least one of an underfill layer, a mold layer, and a dielectric layer on or in the package substrate; and an encapsulation material having a fluorescent chemical compound and an epoxy.

In example 2, the subject matter of example 1 can optionally include the encapsulation material incorporated into at least one of the underfill layer, the mold layer, and the dielectric layer on or in the package substrate. The underfill layer is disposed between the dies and the package substrate. The mold layer is disposed on and around the dies, the underfill layer, and the package substrate. The dielectric layer is disposed in the package substrate.

In example 3, the subject matter of any of examples 1-2 can optionally include the dies electrically coupled to one another by an embedded interconnect bridge disposed in the package substrate.

In example 4, the subject matter of any of examples 1-3 can optionally include the fluorescent chemical compound of the encapsulation material includes at least one of a poly(vinylcarbazole) (PVCz), a 1,4-Bis(5-phenyl-2-oxazolyl) benzene (POPOP), and a plurality of one or more conjugated, aromatic molecules and polymers.

In example 5, the subject matter of any of examples 1-4 can optionally include the encapsulation material which includes between approximately a 0.1 weight percentage to a 2 weight percentage of the fluorescent chemical compound.

In example 6, the subject matter of any of examples 1-5 can optionally include the encapsulation material which includes at least one of a hardener, a filler, an additive, and one or more polymers.

In example 7, the subject matter of any of examples 1-6 can optionally include the epoxy which includes a plurality of one or more epoxy resins. The hardener includes at least one of amines, phenols, and anhydrides. The filler includes at least one of silica, alumina, boron nitride, and zinc oxide. The additive includes at least one of colorants, catalysts, inhibitors, ion trappers, stress absorbers, polymers, surfactants, binding agents, and fluxing agents. The one or more polymers include at least one of acrylates, bismaleimides, polyesters, polyimides, polyolefins, polystyrene, and polyurethanes.

In example 8, the subject matter of any of examples 1-7 can optionally include the dielectric layer disposed on and around the embedded interconnect bridge in the package substrate. The encapsulation material is incorporated into the dielectric layer disposed on and around the embedded interconnect bridge.

Example 9 is a method of forming a semiconductor package, comprising of disposing a fluorescent chemical compound into a solvent to form a fluorescent solution; incorporating the fluorescent solution into an epoxy to form an encapsulation material; and incorporating the encapsulation material into at least one of an underfill layer, a mold layer, and a dielectric disposed on or in a package substrate.

In example 10, the subject matter of example 9 can optionally include disposing dies on the package substrate; disposing the underfill layer between the dies and the package substrate; disposing the mold layer on and around the dies, the underfill layer, and the package substrate; and disposing the dielectric layer in the package substrate.

In example 11, the subject matter of any of examples 9-10 can optionally include the dies electrically coupled to one another by an embedded interconnect bridge disposed in the package substrate.

In example 12, the subject matter of any of examples 9-11 can optionally include the fluorescent chemical compound of the encapsulation material which includes at least one of a PVCz, a POPOP, and a plurality of one or more conjugated, aromatic molecules and polymers.

In example 13, the subject matter of any of examples 9-12 can optionally include the encapsulation material between approximately a 0.1 weight percentage to a 2 weight percentage of the fluorescent chemical compound.

In example 14, the subject matter of any of examples 9-13 can optionally include incorporating at least one of a hardener, a filler, an additive, and one or more polymers into the encapsulation material.

In example 15, the subject matter of any of examples 9-14 can optionally include the epoxy which includes a plurality of one or more epoxy resins. The hardener includes at least one of amines, phenols, and anhydrides, wherein the filler includes at least one of silica, alumina, boron nitride, and zinc oxide, wherein the additive includes at least one of colorants, catalysts, inhibitors, ion trappers, stress absorbers, polymers, surfactants, binding agents, and fluxing agents, and wherein the one or more polymers include at least one of acrylates, bismaleimides, polyesters, polyimides, polyolefins, polystyrene, and polyurethanes.

In example 16, the subject matter of any of examples 9-15 can optionally include the dielectric layer disposed on and around the embedded interconnect bridge in the package substrate. The encapsulation material is incorporated into the dielectric layer disposed on and around the embedded interconnect bridge.

Example 17 is a semiconductor package, comprising of an encapsulation material having a fluorescent chemical compound and an epoxy; an interposer on a package substrate, the package substrate having one or more dielectric layers. A first underfill layer is disposed between the interposer and the package substrate; an embedded interconnect bridge in the package substrate; and one or more dies on the interposer. A second underfill layer is disposed between the one or more dies and the package substrate.

In example 18, the subject matter of example 17 can optionally include a mold layer disposed on and around the one or more dies, the interposer, the first and second underfill layers, and the package substrate.

In example 19, the subject matter of any of examples 17-18 can optionally include the encapsulation material incorporated into at least one of the first and second underfill layers, the mold layer, the interposer, and the package substrate.

In example 20, the subject matter of any of examples 17-19 can optionally include one or more dies electrically coupled to one another by the embedded interconnect bridge disposed in the package substrate.

In example 21, the subject matter of any of examples 17-20 can optionally include the fluorescent chemical compound of the encapsulation material includes at least one of a PVCz, a POPOP, and a plurality of one or more conjugated, aromatic molecules and polymers.

In example 22, the subject matter of any of examples 17-21 can optionally include the encapsulation material between approximately a 0.1 weight percentage to a 2 weight percentage of the fluorescent chemical compound.

In example 23, the subject matter of any of examples 17-22 can optionally include the encapsulation material which includes at least one of a hardener, a filler, an additive, and one or more polymers.

In example 24, the subject matter of any of examples 17-23 can optionally include the epoxy which includes a plurality of one or more epoxy resins. The hardener includes at least one of amines, phenols, and anhydrides. The filler includes at least one of silica, alumina, boron nitride, and zinc oxide. The additive includes at least one of colorants, catalysts, inhibitors, ion trappers, stress absorbers, polymers, surfactants, binding agents, and fluxing agents. The one or more polymers include at least one of acrylates, bismaleimides, polyesters, polyimides, polyolefins, polystyrene, and polyurethanes.

In example 25, the subject matter of any of examples 17-24 can optionally include one or more dielectric layers disposed on and around the embedded interconnect bridge in the package substrate. The encapsulation material is incorporated into the one or more dielectric layers disposed on and around the embedded interconnect bridge.

In the foregoing specification, methods and apparatuses have been described with reference to specific exemplary embodiments thereof. It will be evident that various modifications may be made thereto without departing from the broader spirit and scope. The specification and drawings are, accordingly, to be regarded in an illustrative sense rather than a restrictive sense.

What is claimed is:

1. A semiconductor package, comprising:
a plurality of dies on a package substrate;
at least one of an underfill layer, a mold layer, and a dielectric layer on or in the package substrate; and
an encapsulation material having a fluorescent chemical compound and an epoxy.

2. The semiconductor package of claim 1, wherein the encapsulation material is incorporated into at least one of the underfill layer, the mold layer, or the dielectric layer on or in the package substrate, wherein the underfill layer, if included, is disposed between the dies and the package substrate, wherein the mold layer, if included, is disposed on and around the dies, the underfill layer if included, and the package substrate, and wherein the dielectric layer, if included, is disposed in the package substrate.

3. The semiconductor package of claim 1, wherein the dies are electrically coupled to one another by an embedded interconnect bridge disposed in the package substrate.

4. The semiconductor package of claim 1, wherein the fluorescent chemical compound of the encapsulation material includes at least one of a poly(vinylcarbazole) (PVCz), a 1,4-Bis(5-phenyl-2-oxazolyl) benzene (POPOP), or a plurality of conjugated, aromatic molecules and polymers.

5. The semiconductor package of claim 1, wherein the encapsulation material includes a weight percentage between approximately 0.1% to 2.0% of the fluorescent chemical compound.

6. The semiconductor package of claim 1, wherein the encapsulation material includes at least one of a hardener, a filler, an additive, or a polymer.

7. The semiconductor package of claim 6, wherein the epoxy includes one or more epoxy resins, wherein the hardener, if included, comprises at least one of amines, phenols, or anhydrides, wherein the filler, if included, comprises at least one of silica, alumina, boron nitride, or zinc oxide, wherein the additive, if included, comprises at least one of a colorant, a catalyst, an inhibitor, an ion trapper, a stress absorber, a polymer, a surfactant, a binding agent, or a fluxing agent, and wherein the polymer, if included, comprises at least one of an acrylate, a bismaleimide, a polyester, a polyimide, a polyolefin, a polystyrene, or a polyurethane.

8. The semiconductor package of claim 2, wherein the dielectric layer, if included, is disposed on and around the embedded interconnect bridge in the package substrate, and wherein the encapsulation material is incorporated into the dielectric layer, if included, that is disposed on and around the embedded interconnect bridge.

9. A method of forming a semiconductor package, comprising:
disposing a fluorescent chemical compound into a solvent to form a fluorescent solution;
incorporating the fluorescent solution into an epoxy to form an encapsulation material; and
incorporating the encapsulation material into at least one of an underfill layer, a mold layer, or a dielectric disposed on or in a package substrate.

10. The method of claim 9, further comprising:
disposing a plurality of dies on the package substrate;
disposing the underfill layer, if included, between the dies and the package substrate;
disposing the mold layer, if included, on and around the dies, the underfill layer, and the package substrate; and
disposing the dielectric layer, if included, in the package substrate.

11. The method of claim 10, wherein the dies are electrically coupled to one another by an embedded interconnect bridge disposed in the package substrate.

12. The method of claim 9, wherein the fluorescent chemical compound of the encapsulation material includes at least one of a PVCz, a POPOP, or a plurality of one or more conjugated, aromatic molecules and polymers.

13. The method of claim 9, wherein the encapsulation material includes a weight percentage between approximately 0.1% to 2.0% of the fluorescent chemical compound.

14. The method of claim 9, further comprising incorporating at least one of a hardener, a filler, an additive, or a polymer into the encapsulation material.

15. The method of claim 14, wherein the epoxy includes one or more epoxy resins, wherein the hardener, if included, comprises at least one of amines, phenols, or anhydrides, wherein the filler, if included, comprises at least one of silica, alumina, boron nitride, or zinc oxide, wherein the additive, if included, comprises at least one of a colorant, a catalyst, an inhibitor, an ion trapper, a stress absorber, a polymer, a surfactant, a binding agent, or a fluxing agent, and wherein the polymer, if included, comprises at least one of an acrylate, a bismaleimide, a polyester, a polyimide, a polyolefin, a polystyrene, or a polyurethane.

16. The method of claim 10, wherein the dielectric layer, if included, is disposed on and around the embedded interconnect bridge in the package substrate, and wherein the encapsulation material is incorporated into the dielectric layer, if included, that is disposed on and around the embedded interconnect bridge.

17. A semiconductor package, comprising:
an encapsulation material having a fluorescent chemical compound and an epoxy;
an interposer on a package substrate, the package substrate having one or more dielectric layers, wherein a first underfill layer is disposed between the interposer and the package substrate;
an embedded interconnect bridge in the package substrate; and
one or more dies on the interposer, wherein a second underfill layer is disposed between the one or more dies and the package substrate.

18. The semiconductor package of claim 17, further comprising a mold layer disposed on and around the one or more dies, the interposer, the first and second underfill layers, and the package substrate.

19. The semiconductor package of claim 18, wherein the encapsulation material is incorporated into at least one of the first underfill layer, the second underfill layer, the mold layer, the interposer, or the package substrate.

20. The semiconductor package of claim 17, wherein the one or more dies are electrically coupled to one another by the embedded interconnect bridge disposed in the package substrate.

21. The semiconductor package of claim 17, wherein the fluorescent chemical compound of the encapsulation material includes at least one of a PVCz, a POPOP, or a plurality of conjugated, aromatic molecules and polymers.

22. The semiconductor package of claim 17, wherein the encapsulation material includes a weight percentage between approximately 0.1% to 2.0% of the fluorescent chemical compound.

23. The semiconductor package of claim 17, wherein the encapsulation material includes at least one of a hardener, a filler, an additive, or a polymer.

24. The semiconductor package of claim 23, wherein the epoxy includes one or more epoxy resins, wherein the hardener, if included, comprises at least one of amines, phenols, or anhydrides, wherein the filler, if included, comprises at least one of silica, alumina, boron nitride, or zinc oxide, wherein the additive, if included, comprises at least one of a colorant, a catalyst, an inhibitor, an ion trapper, a stress absorber, a polymer, a surfactant, a binding agent, or a fluxing agent, and wherein the polymer, if included, comprises at least one of an acrylate, a bismaleimide, a polyester, a polyimide, a polyolefin, a polystyrene, or a polyurethane.

25. The semiconductor package of claim 17, wherein the one or more dielectric layers are disposed on and around the embedded interconnect bridge in the package substrate, and wherein the encapsulation material, if included, is incorporated into the one or more dielectric layers disposed on and around the embedded interconnect bridge.
